(19) United States
(12) Patent Application Publication
(10) Pub. No.: US 2021/0408130 A1
(43) Pub. Date: Dec. 30, 2021

(54) FILTER OF QUANTUM DOT DISPLAY PANEL

(71) Applicant: SHENZHEN CHINA STAR OPTOELECTRONICS SEMICONDUCTOR DISPLAY TECHNOLOGY CO., LTD., Shenzhen (CN)

(72) Inventor: Su PAN, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/626,353

(22) PCT Filed: Nov. 25, 2019
(86) PCT No.: PCT/CN2019/120652

§ 371 Date: Dec. 24, 2019

(30) Foreign Application Priority Data
Nov. 8, 2019 (CN) 201911090438.2

(51) Int. Cl. H01L 27/32; H01L 51/52; H01L 51/50; H01L 51/56

(52) U.S. Cl. CPC H01L 27/322; H01L 51/56; H01L 51/502; H01L 51/5293

(57) ABSTRACT

The present application provides a quantum dot display panel and a manufacturing method thereof. The quantum dot display panel includes a pixel layer, a color filter layer, a reflective filter layer, and a circular polarizer which are disposed in a stack. When the quantum dot display panel of the present application is in a dark state, an excitation of the red quantum dots and the green quantum dots is stopped, a problem of reflecting the ambient light by the metal electrode in the blue backlight is also eliminated, maintaining contrast of the quantum dot display panel.

### CROSS-REFERENCE TO RELATED APPLICATIONS

This application claims the priority to Chinese Patent Application No. 2019110904382, entitled “FILTER OF QUANTUM DOT DISPLAY PANEL” and filed on Nov. 8, 2019 with the State Intellectual Property Office of the People's Republic of China, which is entirely incorporated by reference into the present application.

### FIELD OF APPLICATION

The present application is related to the field of quantum dot display panel technology, and specifically to a filter of a quantum dot display panel.

### BACKGROUND OF APPLICATION

Quantum dots (QDs) are tiny semiconductor particles on the nanometer scale. Their optical and electronic properties are different from larger ordinary particles due to quantum mechanics. When a quantum dot receives external light, electrons in the quantum dot are excited, and the electrons transit from a valence band to a conduction band. When the excited electrons return to the valence band again, it will accompany light emission to release its energy, and this is a so-called photo-emissive quantum dot. In addition, the quantum dots also emit light due to the energy provided by an electric field, and this is a so-called electro-emissive quantum dot.

A size of the quantum dot will affect its luminous characteristics. A larger quantum dot, which has a diameter of about 5-6 nanometers, emits light having a longer wavelength such as orange or red light when it is excited. A smaller quantum dot, which has a diameter of about 2-3 nanometers, emits light having shorter wavelength such as blue or green light when it is excited. Therefore, different-sized quantum dots can be used to obtain different colors of light. Light emitted by quantum dots has high color purity, and a narrow and symmetrical distributed emission spectrum. Furthermore the quantum dots have high luminous efficiency, and their quantum efficiency is as high as 90%. The display panel made of the quantum dots has good color expressiveness and high saturation, and the color gamut covered is greater than 100% of National Television Standards Committee (NTSC).

However, because current technology of electro-emissive quantum dots cannot be applied to mass produced display panels, current quantum dot display panels on the market are all made of photo-emissive quantum dots. Currently there are two main types of photo-emissive quantum dot display panels on the market. One type is an improved liquid crystal displays (LCD), which replaces a traditional white backlight with a blue light-emitting diode (blue-LED) and a quantum dot film, and it directly outputs three colors of red, green, and blue, which are relatively pure colors. As a result, it obtains a better backlight utilization and improves a color space of display panels. This type is called quantum dot enhancement film (QDEF) technology, and its products on the market are called QD-enhanced TV. The other type is an improved organic light-emitting diode (OLED) display panels, which replaces traditional red and green OLEDs with red and green quantum dots, and it is uniformly illuminated by blue OLED, and the red and the green quantum dots are used to convert light of blue OLED. As a result, it solves problems of uneven lifespan of three colors and screen burn-in in the traditional OLED display panels, retains advantages of the OLED display panels, and provides the OLED display panels to output relatively pure light. This is called quantum dot color filter (QDCF) technology, and its products on the market are called QD-OLED TV.

Although QD-OLED TV has many advantages, it is inevitable that ambient light will cause quantum dots in its display panel to emit light. When ambient light enters the display panel of the QD-OLED TV, even if the display panel is in a dark state, the ambient light will excite the quantum dots in the display panel to emit light, reducing display contrast of the display panel and affecting viewing experience of users.

A structure of the display panel of the QD-OLED TV is shown in FIG. 1, which is a structural diagram of a quantum dot display panel in the prior art. The quantum dot display panel includes a pixel layer 100 and a blue backlight source 500. The pixel layer 100 includes a plurality of sub-pixels 120, and two out of every three of the plurality of sub-pixels 120 are filled with red quantum dots 121 and green quantum dots 122. The blue backlight source 500 is disposed under the pixel layer 100.

Light of the blue backlight source 500 passes through each of the plurality of sub-pixels 120 from below the pixel layer 100 to above the pixel layer 100. The light of the blue backlight source 500 excites the red quantum dots 121 and the green quantum dots 122, so that the red quantum dots 121 emit red light, and the green quantum dots 122 emit green light. Therefore, every three of the plurality of sub-pixels 120 can display red, green, and blue light.

Because the red quantum dots 121 and the green quantum dots 122 are photo-emissive quantum dots, they excited by any light sources to emit light. When the quantum dot display panel is in operation, the blue backlight source 500 provides display light to the quantum dot display panel. However, ambient light 610 entering the quantum dot display panel additionally excites the red quantum dots 121 and the green quantum dots 122 to emit light, which generates excitation light 611 of quantum dots beyond the operation of the quantum dot display panel. Meanwhile, a metal electrode in the blue backlight source 500 also reflects a part of the ambient light 610, and generates reflected light 612 beyond the operation of the quantum dot display panel.

### SUMMARY OF APPLICATION

Even if a quantum dot display panel is in a dark state, ambient light will excite red quantum dots and green quantum dots to emit light, and cause a metal electrode in a blue backlight source to reflect unnecessary light, reducing display contrast of the quantum dot display panel and affecting viewing experience of users.

In order to solve the problem above, the present application provides a quantum dot display panel, including a pixel layer, a color filter layer, a reflective filter layer, and a circular polarizer. The pixel layer includes a plurality of retaining walls and a plurality of sub-pixels defined between the plurality of retaining walls. The color filter layer is disposed on the pixel layer and includes a plurality of color filters. The reflective filter layer is disposed on the color filter layer and includes a substrate and a reflective filter disposed on the substrate. The reflective filter includes at least one first film and at least one second film, each of the at least one first film has a first refractive index, each of the at least one second film has a second refractive index, and the first refractive index and the second refractive index are different. The circular polarizer is disposed on the reflective filter layer.

In the present application, the quantum dot display panel further includes a blue backlight source disposed under the pixel layer, and the blue backlight source is a light source of a blue organic light-emitting diode or a blue micro light-emitting diode.

In the present application, light of the blue backlight source passes through each of the plurality of sub-pixels from below the pixel layer to above the pixel layer.

In the present application, two out of every three of the plurality of sub-pixels are filled with red quantum dots and green quantum dots.

In the present application, the plurality of retaining walls, the red quantum dots, and the green quantum dots are formed by photolithography or an inkjet printing process.

In the present application, the plurality of color filters includes a plurality of red filters and a plurality of green filters. Each of the plurality of red filters is disposed corresponding to each of the red quantum dots, and each of the plurality of green filters is disposed corresponding to each of the green quantum dots.

In the present application, each of the at least one first film and each of the at least one second film are stacked alternately.

In the present application, one second film is disposed between two neighboring first films.

In the present application, the at least one first film is a silicon oxide film or a material having a high refractive index, and the at least one second film is a magnesium fluoride film or a material having a low refractive index.

In the present application, each of the at least one first film and each of the at least one second film are alternately formed on the substrate by evaporation, sputtering, or chemical vapor deposition.

The present application further provides a manufacturing method of a quantum dot display panel including the steps of:

Step S10: forming a pixel layer, wherein the pixel layer includes a plurality of retaining walls and a plurality of sub-pixels defined between the plurality of retaining walls.

Step S20: forming a color filter layer on the pixel layer, wherein the color filter layer includes a plurality of color filters.

Step S30: forming a reflective filter layer on the color filter layer, wherein the reflective filter layer includes a substrate and a reflective filter disposed on the substrate, the reflective filter includes at least one first film and at least one second film, each of the at least one first film has a first refractive index, each of the at least one second film has a second refractive index, and the first refractive index and the second refractive index are different.

Step S40: forming a circular polarizer on the reflective filter layer.

In the present application, the manufacturing method of the quantum dot display panel further includes the step of:

Step S50: forming a blue backlight source under the pixel layer, wherein the blue backlight source is a light source of a blue organic light-emitting diode or a blue micro light-emitting diode.

In the present application, light of the blue backlight source passes through each of the plurality of sub-pixels from below the pixel layer to above the pixel layer.

In the present application, the step S10 further includes the step of:

step S11: filling two out of every three of the plurality of sub-pixels with red quantum dots and green quantum dots.

In the present application, the step S10 further includes the step of:

step S12: forming the plurality of retaining walls, the red quantum dots, and the green quantum dots by photolithography or an inkjet printing process.

In the step S20 of the present application, the plurality of color filters includes a plurality of red filters and a plurality of green filters; and

each of the plurality of red filters is disposed corresponding to each of the red quantum dots, and each of the plurality of green filters is disposed corresponding to each of the green quantum dots.

In the step S30 of the present application, each of the at least one first film and each of the at least one second film are stacked alternately.

In the present application, one second film is disposed between two neighboring first films.

In the step S30 of the present application, the at least one first film is a silicon oxide film or a material having a high refractive index, and the at least one second film is a magnesium fluoride film or a material having a low refractive index.

In the present application, the step S30 further includes the step of:

step S31: alternately forming each of the at least one first film and each of the at least one second film on the substrate by evaporation, sputtering, or chemical vapor deposition.

Compared to the prior art, the present application combines effects of the reflective filter layer, the color filter layer, and the circular polarizer. When the quantum dot display panel is in a dark state, an excitation of the red quantum dots and the green quantum dots is stopped, a problem of reflecting the ambient light by the metal electrode in the blue backlight is also eliminated, maintaining contrast of the quantum dot display panel.

### DESCRIPTION OF DRAWINGS

In order to further understand detailed technical content and specific implementation of the present application, please refer to the accompanying drawings of the present application. However, the drawings are only provided for reference and explanation, and are not intended to limit the present application.

FIG. 1 is a structural diagram of a quantum dot display panel in the prior art.

FIG. 2 is a structural diagram of a reflective filter layer of the present application.

FIGS. 3 to 5 are structural diagrams of manufacturing processes of a quantum dot display panel of the present application.

FIG. 6 are transmission spectra of color filters of the present application.

FIG. 7 are emission spectra of quantum dots of the present application.

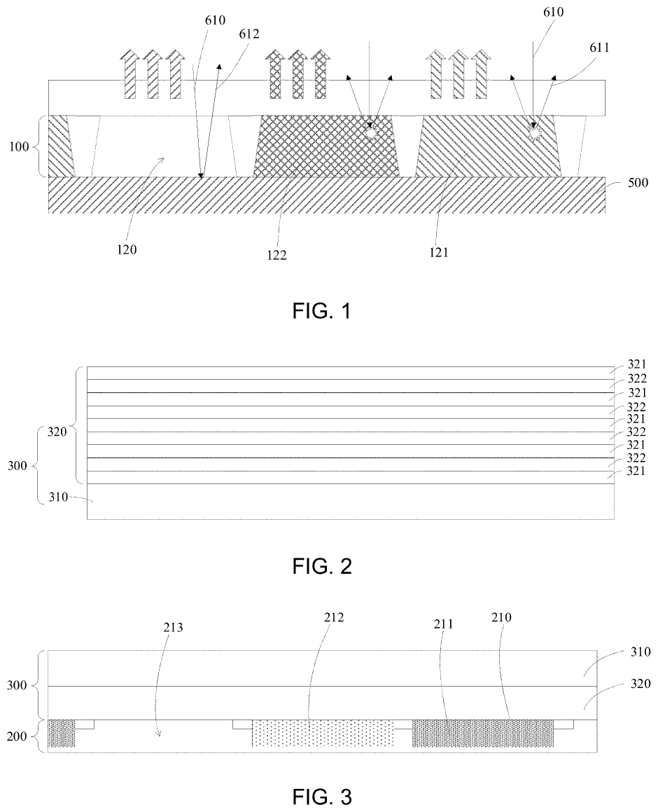

### DETAILED DESCRIPTION OF PREFERRED EMBODIMENTS

The features and spirit of the present application are described more clearly by the following detailed description of preferred embodiments, rather than limiting the scope of the present application with the disclosed preferred embodiments. On the contrary, the present application is to cover various changes and equivalent arrangements within the scope of claims of the present application.

FIG. 2 is a structural diagram of a reflective filter layer of the present application.

The reflective filter layer 300 of the present application includes a substrate 310 and a reflective filter 320 disposed on the substrate 310. The reflective filter 320 includes at least one first film 321 and at least one second film 322, each of the at least one first film 321 has a first refractive index, each of the at least one second film 322 has a second refractive index, and the first refractive index and the second refractive index are different.

A thickness d of each of the at least one first film 321 and each of the at least one second film 322 is related to their refractive index n. An optical thickness value nxd must satisfy ¼ of a wavelength λ of light, which means that nd=λ/4. When the optical thickness value nd is equal to a quarter of the wavelength A of the light, interference will be maximumly enhanced or become destructive interference. Therefore, by controlling a method of stacking, the thickness, and a material of each of the at least one first film 321 and each of the at least one second film 322, an ideal interference effect can be obtained.

The first refractive index and the second refractive index of the present application are different. Each of the at least one first film 321 and each of the at least one second film 322 are stacked alternately. For example, each of the at least one first film 321 and each of the at least one second film 322 are stacked in a manner of 321-322-321-322- . . . , which can obtain a plurality of refractive index differences An between the first refractive index and the second refractive index. Each of the at least one first film 321 has the first refractive index n1, and each of the at least one second film 322 has the second refractive index n2. When the plurality of refractive index differences Δn=n1-n2 are larger, the present application can stack less of the at least one first film 321 and the at least one second film 322 to achieve a higher reflectance.

Besides, number of the at least one first film 321 and the at least one second film 322 is constant. The larger the plurality of refractive index differences An, the larger the reflectance. This application further adjusts the method of stacking each of the at least one first film 321 and each of the at least one second film 322: one second film 322 is disposed between two neighboring first films 321. For example, each of the at least one first film 321 and each of the at least one second film 322 are stacked in a manner of 321-322-321-322- . . . -322-321. When the at least one first film 321 and the at least one second film 322 are stacked to a certain number, the reflectance approaches 100%.

Accordingly, the at least one first film 321 is a silicon oxide film or a material having a high refractive index, and the at least one second film 322 is a magnesium fluoride film or a material having a low refractive index. Each of the at least one first film 321 and each of the at least one second film 322 are alternately formed on the substrate by evaporation, sputtering, or chemical vapor deposition. By stacking each of the at least one first film 321 and each of the at least one second film 322 having different refractive indexes in the reflective filter 320, when ambient light enters the reflective filter layer 300, it will be optically interfered by the reflective filter 320, and most of it will be reflected back.

FIGS. 3 to 5 are structural diagrams of manufacturing processes of a quantum dot display panel of the present application.

First, as shown in FIG. 3, a color filter layer 200 is disposed on the prepared reflective filter layer 300. In the color filter layer 200, a plurality of color filters 210 are formed on a side of the reflection filter 320 of the reflection filter layer 300 by photolithography, and the plurality of color filters 210 include a plurality of red filters 211 and a plurality of green filters 212. The plurality of color filters 210 are stacked in a manner of 211-212-a blank space 213-211-212-a blank space 213. . . . A width of the blank space 213 is same as a width of each of the plurality of color filters 210, and no any of the plurality of color filters 210 is disposed in the blank space 213.

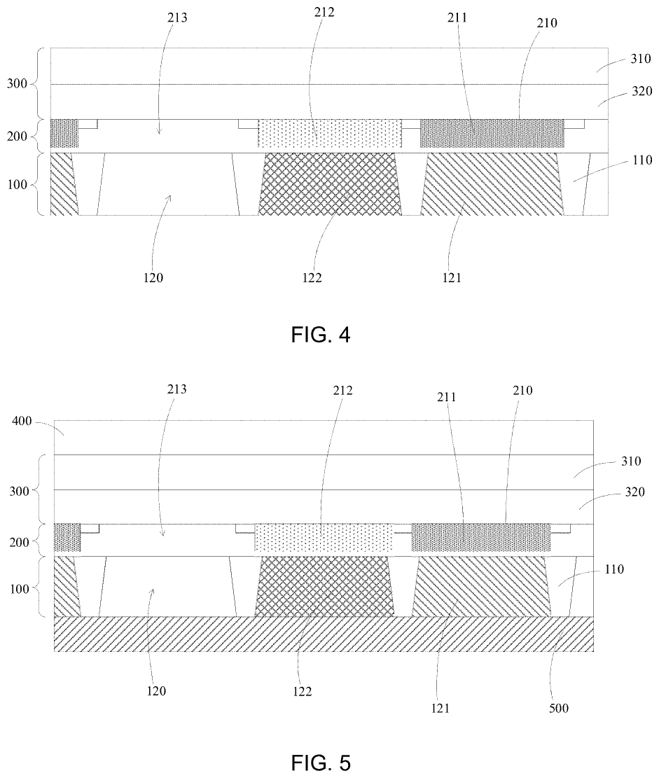

Second, as shown in FIG. 4, a pixel layer 100 is disposed on the color filter layer 200. In the pixel layer 100, a plurality of retaining walls 110 are formed by photolithography or an inkjet printing process. A position of each of the plurality of retaining walls 110 must be aligned between any two color filters 210 or between the blank space 213 and each of the plurality of color filters 210. A plurality of sub-pixels 120 are defined between the plurality of retaining walls 110. Two out of every three of the plurality of sub-pixels 120 are filled with red quantum dots 121 and green quantum dots 122 by the photolithography or the inkjet printing process. Each of the red quantum dots 121 corresponds to each of the plurality of red filters 211, each of the green quantum dots 122 corresponds to each of the plurality of green filters 212, and each of the blank spaces 213 in the color filter layer 200 corresponds to each of the plurality of sub-pixels 120 that is not filled with red quantum dots 121 and green quantum dots 122.

At last, as shown in FIG. 5, a circular polarizer 400 is disposed on the reflective filter layer 300, and a blue backlight source 500 is disposed on the pixel layer 100. The circular polarizer 400 is attached onto a side of the reflective filter layer 300 opposite to the color filter layer 200. The circular polarizer 400 can absorb a part of the ambient light reflected by metal electrode in the blue backlight source 500, and absorb the ambient light reflected by the reflective filter 320. The blue backlight source 500 is attached on a side of the pixel layer 100 opposite to the color filter layer 200. The blue backlight source 500 is a light source of a blue organic light-emitting diode (blue OLED) or a blue micro light-emitting diode (micro LED). Light of the blue backlight source 500 passes through each of the plurality of sub-pixels 120 from below the pixel layer 100 to above the pixel layer 100. The light of the blue backlight source 500 excites the red quantum dots 121 and the green quantum dots 122, so that the red quantum dots 121 emit red light, and the green quantum dots 122 emit green light. Therefore, every three of the plurality of sub-pixels 120 can display red, green, and blue light.

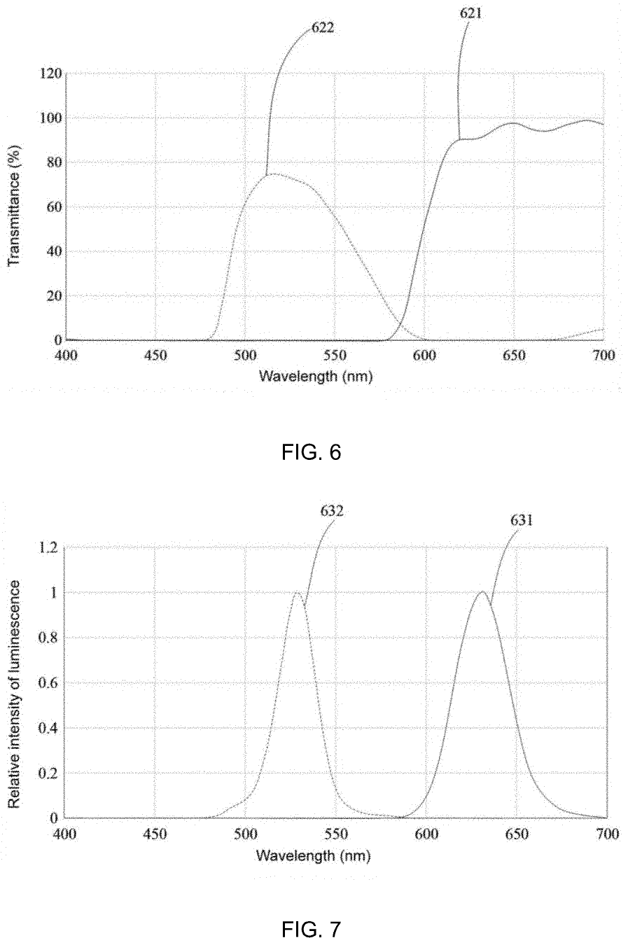

FIG. 6 are transmission spectra of color filters of the present application. FIG. 7 are emission spectra of quantum dots of the present application. In FIG. 6, a transmission spectrum of the plurality of red filters 211 is 621, and a transmission spectrum of the plurality of green filters 212 is 622. A transmission wavelength of the plurality of red filters 211 is more than 580 nm, and a transmission wavelength of the plurality of green filters 212 range from 480 to 600 nm. In FIG. 7, an emission spectrum of the red quantum dots 121 is 631, and an emission spectrum of the green quantum dots 122 is 632. A light-emitting wavelength of the red quantum dots 121 ranges from 600 to 660 nm, and the light-emitting wavelength of the green quantum dots 122 ranges from 500 to 560 nm. Therefore, an ambient light with a wavelength ranging from 580 to 600 nm will excite the red quantum dots 121 to emit light, and an ambient light with a wavelength ranging from 480 to 500 nm will excite the green quantum dots 122 to emit light. The plurality of red filters 211 and the plurality of green filters 212 use pigment to absorb a specific wavelength range of light. Although it can reduce transmission of part of the ambient light, it is still not easy to completely prevent the ambient light from exciting quantum dots to emit light, which means that a design of a narrow-band filter fitting requirements cannot be obtained through the color filter layer 200 singularly.

Accordingly, the color filter layer 200 combines with the reflective filter layer 300 to form a narrow-band filter fitting the requirements, which effectively prevent the ambient light from additionally exciting the red quantum dots 121 and the green quantum dots 122 to emitting light. The circular polarizer 400 is used to absorb a part of the ambient light reflected by metal electrode in the blue backlight source 500, and absorb the ambient light reflected by the reflective filter 320. When the quantum dot display panel of the present application is in a dark state, an excitation of the red quantum dots and the green quantum dots is stopped, a problem of reflecting the ambient light by the metal electrode in the blue backlight is also eliminated, maintaining contrast of the quantum dot display panel.

Although the present application has been disclosed above with the preferred embodiments, it is not intended to limit the present application. Persons having ordinary skill in this technical field can still make various alterations and modifications without departing from the scope and spirit of this application. Therefore, the scope of the present application should be defined and protected by the following claims and their equivalents.

What is claimed is:

1. A quantum dot display panel, comprising:
a pixel layer comprising a plurality of retaining walls and a plurality of sub-pixels defined between the plurality of retaining walls;
a color filter layer disposed on the pixel layer and comprising a plurality of color filters;
a reflective filter layer disposed on the color filter layer and comprising a substrate and a reflective filter disposed on the substrate, wherein the reflective filter comprises at least one first film and at least one second film, each of the at least one first film has a first refractive index, each of the at least one second film has a second refractive index, and the first refractive index and the second refractive index are different; and
a circular polarizer disposed on the reflective filter layer.

2. The quantum dot display panel as claimed in claim 1, wherein the quantum dot display panel further comprises a blue backlight source disposed under the pixel layer, and the blue backlight source is a light source of a blue organic light-emitting diode or a blue micro light-emitting diode.

3. The quantum dot display panel as claimed in claim 2, wherein light of the blue backlight source passes through each of the plurality of sub-pixels from below the pixel layer to above the pixel layer.

4. The quantum dot display panel as claimed in claim 3, wherein two out of every three of the plurality of sub-pixels are filled with red quantum dots and green quantum dots.

5. The quantum dot display panel as claimed in claim 4, wherein the plurality of retaining walls, the red quantum dots, and the green quantum dots are formed by photolithography or an inkjet printing process.

6. The quantum dot display panel as claimed in claim 4, wherein the plurality of color filters comprises a plurality of red filters and a plurality of green filters; and
each of the plurality of red filters is disposed corresponding to each of the red quantum dots, and each of the plurality of green filters is disposed corresponding to each of the green quantum dots.

7. The quantum dot display panel as claimed in claim 1, wherein each of the at least one first film and each of the at least one second film are stacked alternately.

8. The quantum dot display panel as claimed in claim 7, wherein one second film is disposed between two neighboring first films.

9. The quantum dot display panel as claimed in claim 1, wherein the at least one first film is a silicon oxide film or a material having a high refractive index, and the at least one second film is a magnesium fluoride film or a material having a low refractive index.

10. The quantum dot display panel as claimed in claim 1, wherein each of the at least one first film and each of the at least one second film are alternately formed on the substrate by evaporation, sputtering, or chemical vapor deposition.

11. A manufacturing method of a quantum dot display panel, comprising the steps of:
step S10: forming a pixel layer, wherein the pixel layer comprises a plurality of retaining walls and a plurality of sub-pixels defined between the plurality of retaining walls;
step S20: forming a color filter layer on the pixel layer, wherein the color filter layer comprises a plurality of color filters;
step S30: forming a reflective filter layer on the color filter layer, wherein the reflective filter layer comprises a substrate and a reflective filter disposed on the substrate, the reflective filter comprises at least one first film and at least one second film, each of the at least one first film has a first refractive index, each of the at least one second film has a second refractive index, and the first refractive index and the second refractive index are different; and
step S40: forming a circular polarizer on the reflective filter layer.

12. The manufacturing method of the quantum dot display panel as claimed in claim 11, further comprising the step of:
step S50: forming a blue backlight source under the pixel layer, wherein the blue backlight source is a light source of a blue organic light-emitting diode or a blue micro light-emitting diode.

13. The manufacturing method of the quantum dot display panel as claimed in claim 12, wherein light of the blue backlight source passes through each of the plurality of sub-pixels from below the pixel layer to above the pixel layer.

14. The manufacturing method of the quantum dot display panel as claimed in claim 13, wherein the step S10 further comprises the step of:
step S11: filling two out of every three of the plurality of sub-pixels with red quantum dots and green quantum dots.

15. The manufacturing method of the quantum dot display panel as claimed in claim 14, wherein the step S10 further comprises the step of:
step S12: forming the plurality of retaining walls, the red quantum dots, and the green quantum dots by photolithography or an inkjet printing process.

16. The manufacturing method of the quantum dot display panel as claimed in claim 14, wherein in the step S20, the plurality of color filters comprises a plurality of red filters and a plurality of green filters; and
each of the plurality of red filters is disposed corresponding to each of the red quantum dots, and each of the plurality of green filters is disposed corresponding to each of the green quantum dots.

17. The manufacturing method of the quantum dot display panel as claimed in claim 11, wherein in the step S30, each of the at least one first film and each of the at least one second film are stacked alternately.

18. The manufacturing method of the quantum dot display panel as claimed in claim 17, wherein one second film is disposed between two neighboring first films.

19. The manufacturing method of the quantum dot display panel as claimed in claim 11, wherein in the step S30, the at least one first film is a silicon oxide film or a material having a high refractive index, and the at least one second film is a magnesium fluoride film or a material having a low refractive index.

20. The manufacturing method of the quantum dot display panel as claimed in claim 11, wherein the step S30 further comprises the step of:
step S31: alternately forming each of the at least one first film and each of the at least one second film on the substrate by evaporation, sputtering, or chemical vapor deposition.
